(19) United States
(12) Patent Application Publication
(10) Pub. No.: US 2024/0023236 A1
(43) Pub. Date: Jan. 18, 2024

(54) CIRCUIT BOARD ASSEMBLY WITH INTEGRATED AIRFLOW PATH

(71) Applicant: Dell Products L.P., Round Rock, TX (US)

(72) Inventors: Robert B. CURTIS, Georgetown, TX (US); Eric TUNKS, Austin, TX (US)

(73) Assignee: Dell Products L.P., Round Rock, TX (US)

(21) Appl. No.: 17/863,460

(22) Filed: Jul. 13, 2022

(51) Int. Cl. H05K 1/02

(52) U.S. Cl. CPC H05K 1/0272; H05K 1/0203

(57) ABSTRACT

A circuit board assembly may include an integrated airflow path formed with a partially closed volume to direct airflow received at a first opening of the integrated airflow path through the integrated airflow path and to a second opening of the integrated airflow path, a circuit board mechanically coupled to the integrated airflow path such that at least a portion of the circuit board resides within the partially closed volume, and a connector electrically and mechanically coupled to the circuit board and configured to electrically and mechanically couple a device received in the connector to the circuit board.

### TECHNICAL FIELD

The present disclosure relates in general to information handling systems, and more particularly to a circuit board assembly with an integrated airflow path.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems are becoming more and more dense over time, both from a hardware feature and power density perspective. In each subsequent generation of information handling systems, more features are added and the power consumption of those features also increases from generation to generation. Air cooling remains the predominant cooling solution for rack servers, but due to the system and power density trends, air cooling is becoming more and more difficult. Accordingly, systems and methods that enable efficient routing of airflow in an information handling system may be desired.

### SUMMARY

In accordance with the teachings of the present disclosure, the disadvantages and problems associated with existing approaches to routing of airflow in information handling systems may be reduced or eliminated.

In accordance with embodiments of the present disclosure, a circuit board assembly may include an integrated airflow path formed with a partially closed volume to direct airflow received at a first opening of the integrated airflow path through the integrated airflow path and to a second opening of the integrated airflow path, a circuit board mechanically coupled to the integrated airflow path such that at least a portion of the circuit board resides within the partially closed volume, and a connector electrically and mechanically coupled to the circuit board and configured to electrically and mechanically couple a device received in the connector to the circuit board.

In accordance with these and other embodiments of the present disclosure, an information handling system may include an information handling resource and a circuit board assembly comprising an integrated airflow path formed with a partially closed volume to direct airflow received at a first opening of the integrated airflow path through the integrated airflow path and to a second opening of the integrated airflow path, a circuit board mechanically coupled to the integrated airflow path such that at least a portion of the circuit board resides within the partially closed volume, and a connector electrically and mechanically coupled to the circuit board and configured to electrically and mechanically couple the information handling resource received in the connector to the circuit board.

In accordance with these and other embodiments of the present disclosure, a method may include forming an integrated airflow path with a partially closed volume to direct airflow received at a first opening of the integrated airflow path through the integrated airflow path and to a second opening of the integrated airflow path, mechanically coupling a circuit board to the integrated airflow path such that at least a portion of the circuit board resides within the partially closed volume, and electrically and mechanically coupling a connector to the circuit board and configured to electrically and mechanically couple a device received in the connector to the circuit board.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an isometric perspective view of selected components of an example circuit board assembly with integrated airflow path, in accordance with embodiments of the present disclosure;

FIG. 2 illustrates an isometric perspective view of selected components of an example circuit board assembly with integrated airflow path with a device coupled to the example circuit board via a connector of the example circuit board, in accordance with embodiments of the present disclosure;

FIG. 3 illustrates an isometric perspective view of selected components of an information handling system having circuit board assemblies with respectively integrated airflow paths, in accordance with embodiments of the present disclosure; and

FIG. 4 illustrates an isometric perspective view of selected components of another information handling system having circuit board assemblies with respectively integrated airflow paths, in accordance with embodiments of the present disclosure.

### DETAILED DESCRIPTION

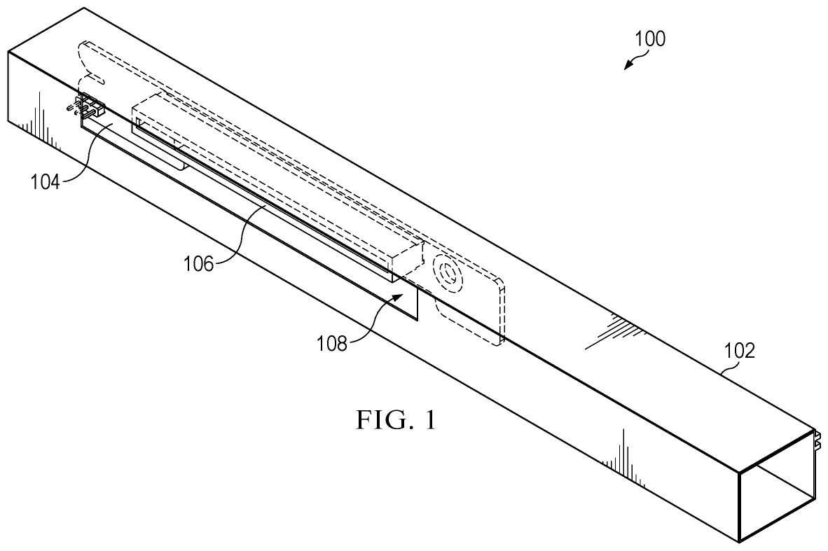

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal data assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, power supplies, air movers (e.g., fans and blowers) and/or any other components and/or elements of an information handling system.

As discussed above, an information handling system may include one or more circuit boards operable to mechanically support and electrically connect electronic components making up the information handling system (e.g., packaged integrated circuits). Circuit boards may be used as part of motherboards, memories, storage devices, storage device controllers, peripherals, peripheral cards, network interface cards, and/or other electronic components. As used herein, the term “circuit board” includes printed circuit boards (PCBs), printed wiring boards (PWBs), etched wiring boards, and/or any other board or similar physical structure operable to mechanically support and electrically couple electronic components.

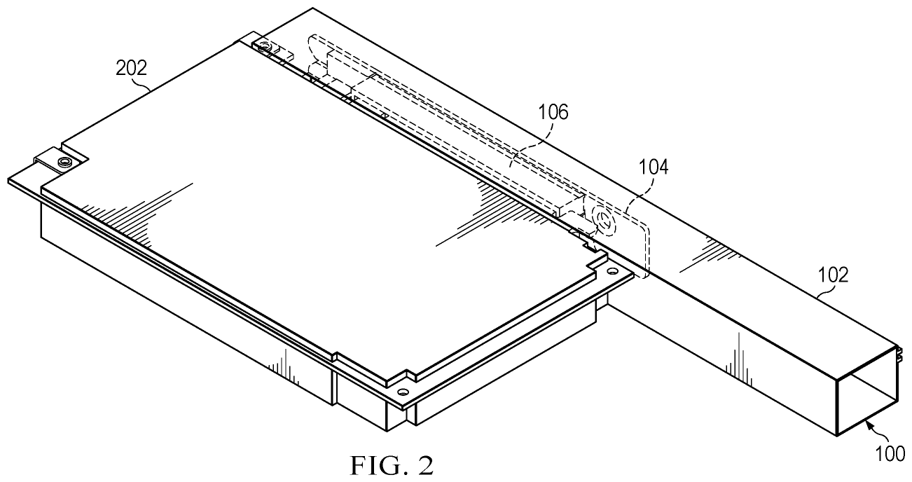

FIG. 1 illustrates an isometric perspective view of selected components of an example circuit board assembly 100 with integrated airflow path 102, in accordance with embodiments of the present disclosure. As shown in FIG. 1, circuit board assembly 100 may include integrated airflow path 102, which may comprise a duct, plenum, or other mechanical structure, and may generally be in the shape of an elongated rectangular prism open at each end and with generally solid sides such that airflow received in one of the ends of integrated airflow path 102 may be guided within integrated airflow path 102 and expelled through the opposite end from which the airflow is received. For illustrative purposes, integrated airflow path 102 is depicted in FIG. 1 (and FIG. 2) as partially transparent, although in actual implementation integrated airflow path 102 may be constructed from an optically opaque material.

As also shown in FIG. 1, circuit board assembly 100 may include a circuit board 104 mechanically mounted to a side of integrated airflow path 102 such that at least a portion of circuit board 104 is internal to integrated airflow path 102. Further, circuit board 104 may have mounted thereon a receptacle connector 106 having mechanical features (e.g., a rigid plastic bracket) and electrically-conductive features (e.g., pins) for receiving a corresponding edge connector, thus electrically coupling electrically conductive traces (e.g., pins) of the edge connector to corresponding electrically-conductive features of receptacle connector 106 and mechanically coupling an information handling resource (e.g., another circuit board) to receptacle connector 106 in order to maintain such electrical coupling.

As an example, in some embodiments, circuit board 104 may comprise a riser card configured to receive a multitude of signal lines (e.g., bused signal lines) via a single connector (e.g., an edge connector of the riser card external to integrated airflow path 102) from a motherboard and distribute such signals lines via dedicated connectors (e.g., one or more receptacle connectors 106) mounted on the riser card. Thus, when implemented as a riser card, circuit board 104 may enable the addition of expansion cards (e.g., Peripheral Component Interconnect Express or “PCIe” cards), particularly where a height of an information handling system chassis does not allow for a perpendicular placement of expansion cards relative to the motherboard.

As additionally shown in FIG. 1, integrated airflow path 102 may include an opening 108 on a side of integrated airflow path 102 opposite the side to which circuit board 104 is mounted, such opening sized and shaped to accommodate physical dimensions of an information handling resource coupled to circuit board 104 via receptacle connector 106. In some embodiments, opening 108 may be sized and shaped such that when an information handling resource is coupled to circuit board 104 via receptacle connector 106, the information handling resource blocks (e.g., either by filling in or blocking opening 108) a significant portion of opening 108 in order to minimize airflow through opening 108.

To that end, FIG. 2 illustrates an isometric perspective view of selected components of example circuit board assembly 100 with integrated airflow path 102 with a device 202 coupled to circuit board 104 via connector 106, in accordance with embodiments of the present disclosure. As shown in FIG. 2, when device 202 is coupled to circuit board 104 via connector 106, a portion of device 202 may significantly block a significant portion of opening 108 in order to minimize airflow through opening 108.

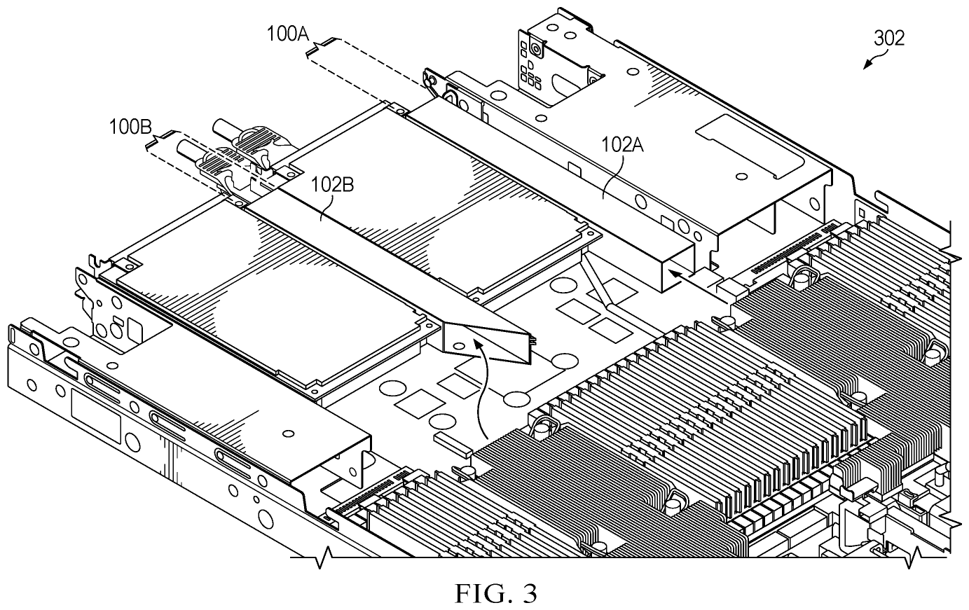

FIG. 3 illustrates an isometric perspective view of selected components of an information handling system 302 having circuit board assemblies 100 (circuit board assembly 100A and circuit board assembly 100B) with respectively integrated airflow paths 102 (integrated airflow path 102A and integrated airflow path 102B), in accordance with embodiments of the present disclosure. Although circuit boards 104 and connectors 106 of circuit board assemblies 100 are not shown in FIG. 3, both may be present in their respective circuit board assemblies 100, as described above with respect to FIGS. 1 and 2.

As shown in FIG. 3, in some instances, one or more ends of an integrated airflow path 102 may be formed such that a rectangle defined by an opening at such end is perpendicular to the length of integrated airflow path 102, as is the case for integrated airflow path 102A depicted in FIG. 3. In addition, in some instances, one or more ends of an integrated airflow path 102 may be formed such that a rectangle defined by an opening at such end is not perpendicular to the length of integrated airflow path 102, as is the case for integrated airflow path 102B depicted in FIG. 3. Formation of such a “slanted” rectangular end such as that of integrated airflow path 102 may allow for receipt of airflow by integrated airflow path 102 in instances in which integrated airflow path 102B is not immediately linearly downstream of the airflow in which it is to receive.

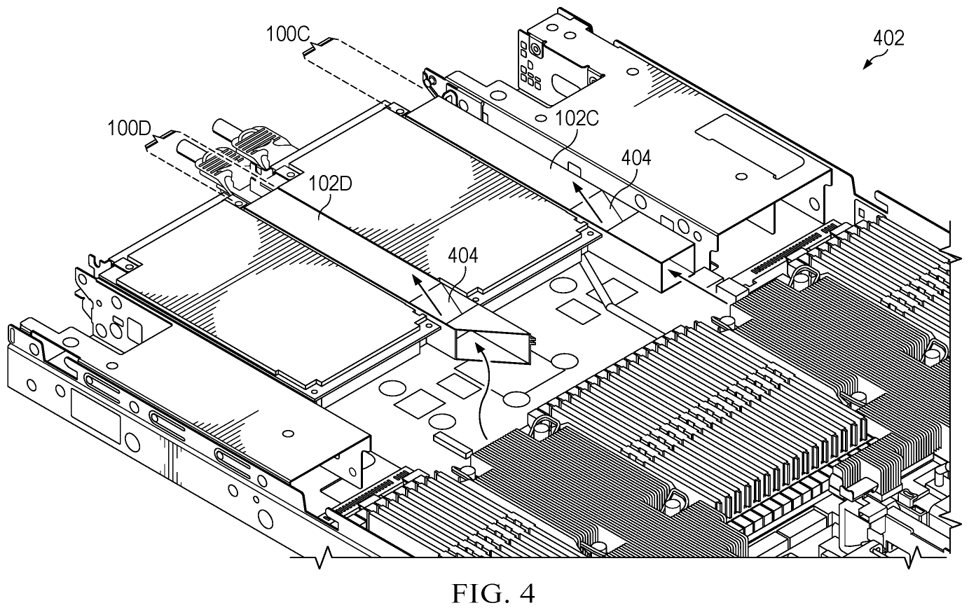

FIG. 4 illustrates an isometric perspective view of selected components of another information handling system 402 having circuit board assemblies 100 (e.g., circuit board assembly 100C and circuit board assembly 100D) with respectively integrated airflow paths (e.g., integrated airflow path 102C and integrated airflow path 102D), in accordance with embodiments of the present disclosure. Information handling system 402 as shown in FIG. 4 is similar in many respects to information handling system 302 as shown in FIG. 3, except that integrated airflow path 102C and integrated airflow path 102D may each include an airflow opening 404 formed in a side thereof (and may each be additionally closed at one end) to enable airflow through such airflow opening 404 (e.g., to push airflow out of a chassis through a top cover of the chassis into space between adjacent chassis, instead of pushing such airflow through the rear of the chassis).

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A circuit board assembly comprising:
an integrated airflow path formed with a partially closed volume to direct airflow received at a first opening of the integrated airflow path through the integrated airflow path and to a second opening of the integrated airflow path;
a circuit board mechanically coupled to the integrated airflow path such that at least a portion of the circuit board resides within the partially closed volume; and
a connector electrically and mechanically coupled to the circuit board and configured to electrically and mechanically couple a device received in the connector to the circuit board.

2. The circuit board assembly of claim 1, wherein the integrated airflow path comprises an opening formed therein opposite from the connector, such that the opening accommodates dimensions of the device received in the connector.

3. The circuit board assembly of claim 1, the opening formed such that the opening is blocked to minimize airflow through the opening when the device is received in the connector.

4. The circuit board assembly of claim 1, the integrated airflow path formed with a plurality of sides and a first opening at a first end of the integrated airflow path.

5. The circuit board assembly of claim 4, the integrated airflow path further formed with a second opening at a second end of the integrated airflow path.

6. The circuit board assembly of claim 4, the integrated airflow path further formed with a second opening in one of the sides of the integrated airflow path.

7. The circuit board assembly of claim 4, the first opening defining a polygon non-perpendicular to a length of the integrated airflow path.

8. An information handling system comprising:
an information handling resource; and
a circuit board assembly comprising:
an integrated airflow path formed with a partially closed volume to direct airflow received at a first opening of the integrated airflow path through the integrated airflow path and to a second opening of the integrated airflow path;
a circuit board mechanically coupled to the integrated airflow path such that at least a portion of the circuit board resides within the partially closed volume; and
a connector electrically and mechanically coupled to the circuit board and configured to electrically and mechanically couple the information handling resource received in the connector to the circuit board.

9. The information handling system of claim 8, wherein the integrated airflow path comprises an opening formed therein opposite from the connector, such that the opening accommodates dimensions of the information handling resource received in the connector.

10. The information handling system of claim 8, the opening formed such that the opening is blocked to minimize airflow through the opening when the information handling resource is received in the connector.

11. The information handling system of claim 8, the integrated airflow path formed with a plurality of sides and a first opening at a first end of the integrated airflow path.

12. The information handling system of claim 11, the integrated airflow path further formed with a second opening at a second end of the integrated airflow path.

13. The information handling system of claim 11, the integrated airflow path further formed with a second opening in one of the sides of the integrated airflow path.

14. The information handling system of claim 11, the first opening defining a polygon non-perpendicular to a length of the integrated airflow path.

15. A method comprising:
forming an integrated airflow path with a partially closed volume to direct airflow received at a first opening of the integrated airflow path through the integrated airflow path and to a second opening of the integrated airflow path;
mechanically coupling a circuit board to the integrated airflow path such that at least a portion of the circuit board resides within the partially closed volume; and
electrically and mechanically coupling a connector to the circuit board and configured to electrically and mechanically couple a device received in the connector to the circuit board.

16. The method of claim 15, further comprising forming an opening therein opposite from the connector, such that the opening accommodates dimensions of the device received in the connector.

17. The method of claim 15, further comprising forming the opening such that the opening is blocked to minimize airflow through the opening when the device is received in the connector.

18. The method of claim 15, further comprising forming the integrated airflow path with a plurality of sides and a first opening at a first end of the integrated airflow path.

19. The method of claim 18, further comprising forming the integrated airflow path with a second opening at a second end of the integrated airflow path.

20. The method of claim 18, further comprising forming the integrated airflow path with a second opening in one of the sides of the integrated airflow path.

21. The method of claim 18, the first opening defining a polygon non-perpendicular to a length of the integrated airflow path.
